(19) United States
(12) Patent Application Publication
(10) Pub. No.: US 2022/0290292 A1
(43) Pub. Date: Sep. 15, 2022

(54) TEMPERATURE CONTROL UNIT AND PROCESSING APPARATUS

(71) Applicant: Tokyo Electron Limited, Tokyo (JP)

(72) Inventors: Takashi YOSHIDA, Oshu City (JP); Shinya TAKAHASHI, Nirasaki City (JP)

(21) Appl. No.: 17/654,625

(22) Filed: Mar. 14, 2022

(30) Foreign Application Priority Data
Mar. 15, 2021 (JP) 2021-041111

(51) Int. Cl. C23C 14/54; C23C 16/52; H01L 21/67

(52) U.S. Cl. CPC C23C 14/54; C23C 16/52; H01L 21/67017

(57) ABSTRACT

A temperature control unit that controls a temperature of a gas valve and includes: a heat sink attached to the gas valve; and a housing that covers the heat sink and includes an introduction port through which a temperature control fluid is introduced.

### CROSS-REFERENCE TO RELATED APPLICATION

This application is based upon and claims the benefit of priority from Japanese Patent Application No. 2021-041111, filed on Mar. 15, 2021, the entire contents of which are incorporated herein by reference.

### TECHNICAL FIELD

The present disclosure relates to a temperature control unit and a processing apparatus.

### BACKGROUND

In a semiconductor manufacturing process, a processing apparatus in which a process gas is supplied into a process container, which accommodates a substrate, to perform a predetermined process on the substrate is used. The processing apparatus is provided with a gas valve that controls supply and stop of the process gas into the process container (see, e.g., Patent Documents 1 and 2).

### PRIOR ART DOCUMENTS

### Patent Documents

Patent Document 1: Japanese Laid-Open Patent Publication No. 2002-299327
Patent Document 2: Japanese Laid-Open Patent Publication No. 2006-057645

### SUMMARY

According to an embodiment of the present disclosure, there is provided a temperature control unit that controls a temperature of a gas valve, including: a heat sink attached to the gas valve; and a housing that covers the heat sink and includes an introduction port through which a temperature control fluid is introduced.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view showing an example of a processing apparatus according to an embodiment of the present disclosure.

FIG. 2 is a perspective view showing an example of a gas valve group included in a processing apparatus of FIG. 1.

FIG. 3 is a perspective view showing an example of a cooling unit attached to a gas valve.

FIG. 4 is a side view showing an example of a cooling unit attached to a gas valve.

FIG. 5 is a cross-sectional view showing an example of a cooling unit attached to a gas valve.

FIG. 6 is a side view showing another example of a cooling unit attached to a gas valve.

FIGS. 7A and 7B are diagrams (1) showing an evaluation result of a cooling time of a gas valve.

FIG. 8 is a diagram (2) showing an evaluation result of a cooling time of a gas valve.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. Throughout the accompanying drawings, the same or corresponding members or components are denoted by the same or corresponding reference numerals, and explanation thereof will not be repeated.

### [Processing Apparatus]

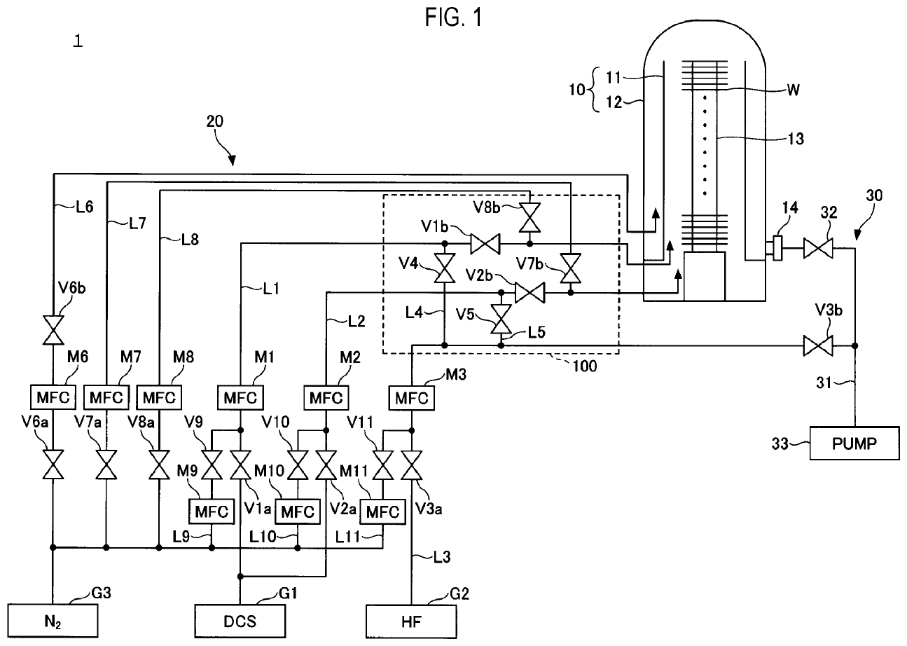

An example of a processing apparatus according to an embodiment of the present disclosure will be described with reference to FIG. 1. In the following, a case where the processing apparatus is a batch-type apparatus that processes a plurality of substrates at a time will be described as an example. However, the processing apparatus is not limited to the batch-type processing apparatus. For example, the processing apparatus may be a single-wafer-type apparatus that processes substrates one by one. Further, for example, the processing apparatus may be a semi-batch-type apparatus that processes a plurality of substrates, and the plurality of substrates arranged on a rotary table in a process container are revolved by the rotary table and are sequentially passed through a region into which a first gas is supplied and a region into which a second gas is supplied.

The processing apparatus 1 includes a process container 10, a gas supply part 20, an exhaust part 30, and so on. In the processing apparatus 1, a predetermined process (for example, a film-forming process) is performed on a plurality of substrates accommodated in the process container 10 by supplying a process gas into the process container 10 by the gas supply part 20. Further, in the processing apparatus 1, the process gas supplied into the process container 10 is exhausted by the exhaust part 30.

The process container 10 has a double-tube structure including an inner tube 11 and an outer tube 12. The inner tube 11 has substantially a cylindrical shape with its upper end opened. The outer tube 12 is provided around the inner tube 11 and has substantially a cylindrical shape with its upper end closed. A boat 13 holding substrates W to be processed in a shelf shape is accommodated inside the inner tube 11. An exhaust port 14 is formed in a lower portion of a sidewall of the outer tube 12.

The gas supply part 20 includes a DCS supply source G1, a HF supply source G2, and a N₂ supply source G3.

The DCS supply source G1 supplies dichlorosilane (DCS; SiH₂Cl₂) into the inner tube 11 via a gas supply line L1. A valve V1a, a mass flow controller M1, and a valve V1b are interposed in the gas supply line L1 sequentially from the side of the DCS supply source G1.

Further, the DCS supply source G1 supplies DCS into the inner tube 11 via a gas supply line L2. A valve V2a, a mass flow controller M2, and a valve V2b are interposed in the gas supply line L2 sequentially from the side of the DCS supply source G1.

The HF supply source G2 supplies hydrogen fluoride (HF) to an exhaust line 31 via a gas supply line L3. A valve V3a, a mass flow controller M3, and a valve V3b are interposed in the gas supply line L3 sequentially from the side of the HF supply source G2.

Further, the HF supply source G2 supplies HF to the gas supply line L1 via the gas supply line L3 and a gas supply line L4. The gas supply line L4 connects between the mass flow controller M3 and the valve V3b in the gas supply line L3 and between the mass flow controller M1 and the valve V1b in the gas supply line L1. A valve V4 is interposed in the gas supply line L4.

Further, the HF supply source G2 supplies HF to the gas supply line L2 via the gas supply line L3 and a gas supply line L5. The gas supply line L5 connects between the mass flow controller M3 and the valve V3b in the gas supply line L3 and between the mass flow controller M2 and the valve V2b in the gas supply line L2. A valve V5 is interposed in the gas supply line L5.

The N₂ supply source G3 supplies nitrogen (N₂) between the inner tube 11 and the outer tube 12 via a gas supply line L6. A valve V6a, a mass flow controller M6, and a valve V6b are interposed in the gas supply line L6 sequentially from the side of the N₂ supply source G3.

Further, the N₂ supply source G3 supplies N₂ to the gas supply line L2 via a gas supply line L7. The gas supply line L7 is connected between the valve V2b in the gas supply line L2 and the process container 10. A valve V7a, a mass flow controller M7, and a valve V7b are interposed in the gas supply line L7 sequentially from the side of the N₂ supply source G3.

Further, the N₂ supply source G3 supplies N₂ to the gas supply line L1 via a gas supply line L8. The gas supply line L8 is connected between the valve V1b in the gas supply line L1 and the process container 10. A valve V8a, a mass flow controller M8, and a valve V8b are interposed in the gas supply line L8 sequentially from the side of the N₂ supply source G3.

Further, the N₂ supply source G3 supplies N₂ to the gas supply line L1 via a gas supply line L9. The gas supply line L9 is connected between the valve V1a in the gas supply line L1 and the mass flow controller M1. A mass flow controller M9 and a valve V9 are interposed in the gas supply line L9 sequentially from the side of the N₂ supply source G3.

Further, the N₂ supply source G3 supplies N₂ to the gas supply line L2 via a gas supply line L10. The gas supply line L10 is connected between the valve V2a in the gas supply line L2 and the mass flow controller M2. A mass flow controller M10 and a valve V10 are interposed in the gas supply line L10 sequentially from the side of the N₂ supply source G3.

Further, the N₂ supply source G3 supplies N₂ to the gas supply line L3 via a gas supply line L11. The gas supply line L11 is connected between the valve V3a in the gas supply line L3 and the mass flow controller M3. A mass flow controller M11 and a valve V11 are interposed in the gas supply line L11 sequentially from the side of the N₂ supply source G3.

The gas supply lines L1 to L11 each include, for example, a gas supply pipe. Further, the valves V1b, V2b, V4, V5, V7b, and V8b constitute a gas valve group 100 to be described later.

The exhaust part 30 includes the exhaust line 31, a valve 32, a vacuum pump 33, and so on. The exhaust line 31 includes, for example, an exhaust pipe and connects the exhaust port 14 and the vacuum pump 33. The valve 32 is interposed in the exhaust line 31 and opens/closes the exhaust line 31. The vacuum pump 33 includes, for example, a dry pump, a turbo molecular pump, and the like and exhausts an interior of the process container 10 via the exhaust line 31.

### [Gas Valve Group]

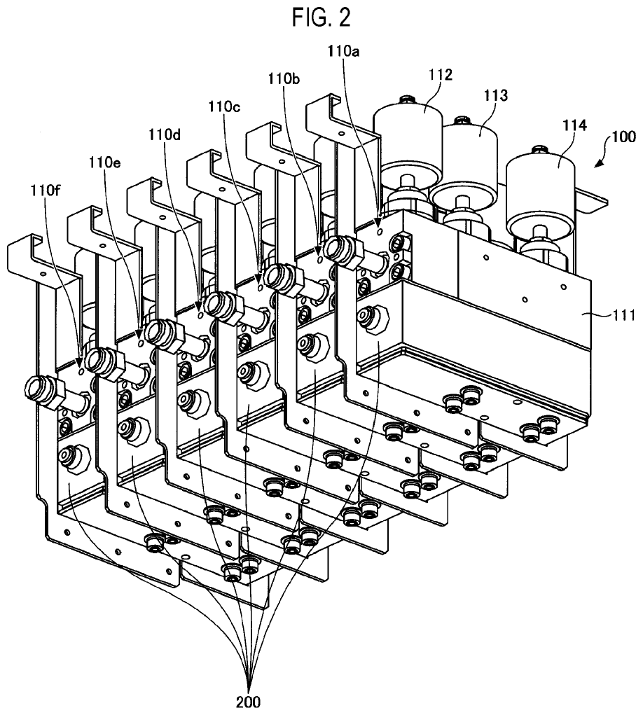

An example of a gas valve group 100 included in the processing apparatus 1 of FIG. 1 will be described with reference to FIG. 2. The gas valve group 100 includes six gas valves 110 (110a to 110f) arranged in a row. The six gas valves 110a to 110f correspond to the six valves V1b, V2b, V4, V5, V7b, and V8b included in the processing apparatus 1 of FIG. 1.

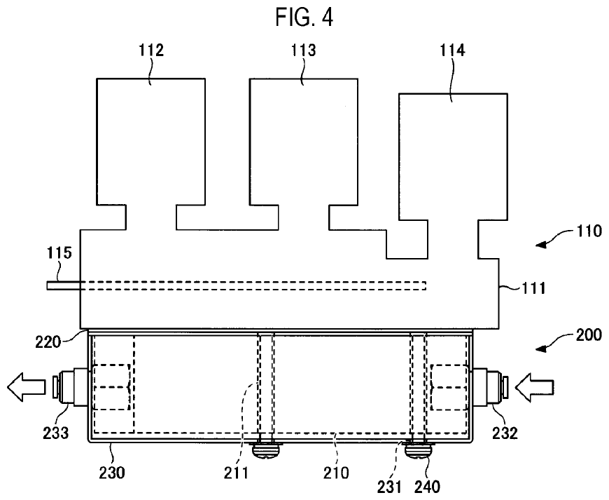

Each gas valve 110 includes a flow path block 111, a vent valve 112, a supply valve 113, a purge valve 114, a heater 115, and so on. The flow path block 111 is formed by molding metal such as stainless steel into substantially a rectangular parallelepiped shape and forming a gas flow path by machining or the like. The vent valve 112, the supply valve 113, and the purge valve 114 are attached to the flow path block 111. Each gas valve 110 controls the supply and stop of the process gas into the process container 10 by opening/closing the flow path by the vent valve 112, the supply valve 113, and the purge valve 114. Further, the heater 115 (FIG. 4) is embedded in the flow path block 111. The heater 115 heats the flow path block 111.

In the processing apparatus of FIG. 1, the temperature of the gas valve group 100 may be changed according to types of processes performed in the process container 10. For example, when a film-forming process is performed in the process container 10, in a state where all of the six gas valves 110a to 110f of the gas valve group 100 are heated to a temperature for film formation, for example, 100 degrees C. to 200 degrees C., a film-forming gas is supplied into the process container 10. For example, when a cleaning process is performed in the process container 10, in a state where at least one of the six gas valves 110a to 110f of the gas valve group 100 is cooled to a temperature for cleaning, for example, 70 degrees C. or lower, a cleaning gas is supplied into the process container 10.

By the way, in a case where the number of gas valves 110 for cooling from the temperature for film formation to the temperature for cleaning is small (for example, one), the time required for cooling the gas valves 110 is not so long. However, in a case where the number of gas valves 110 for cooling from the temperature for film formation to the temperature for cleaning increases, the time required for cooling the gas valves 110 becomes longer.

In the present embodiment, as shown in FIG. 2, by attaching a cooling unit 200 to each of the six gas valves 110a to 110f, a technique capable of cooling the gas valves 110 in a short time is provided. However, the cooling unit 200 may be attached to the gas valves 110 that changes at least a temperature.

### [Cooling Unit]

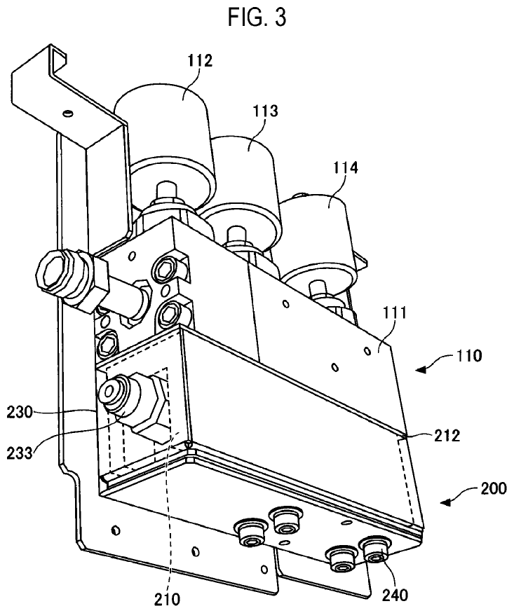

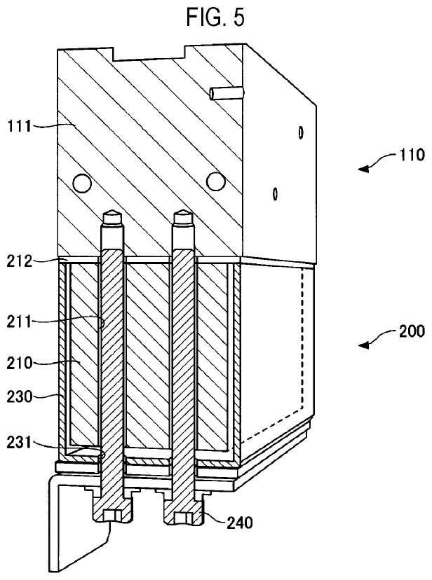

An example of the cooling unit 200 will be described with reference to FIGS. 3 to 5. FIGS. 3, 4, and 5 are a perspective view, a side view, and a cross-sectional view showing an example of a cooling unit 200 attached to a gas valve 110, respectively.

The cooling unit 200 is attached to the lower surface of the gas valve 110 and cools the gas valve 110. The cooling unit 200 includes a heat sink 210, a heat conductive member 220, a housing 230, screws 240, and so on.

The heat sink 210 is attached to the lower surface of a flow path block 111. A plurality of insertion through-holes 211 penetrating in the vertical direction are formed in the heat sink 210. The screw 240 is inserted into each insertion through-hole 211. The heat sink 210 includes a flange portion 212, and the flange portion 212 is fixed to the flow path block 111 by being pressed against the housing 230.

The heat conductive member 220 is interposed between the gas valve 110 and the heat sink 210 and improves the heat conductivity between the gas valve 110 and the heat sink 210. The heat conductive member 220 is, for example, a heat conductive double-sided tape.

The housing 230 is provided so as to cover the heat sink 210. As a result, when the gas valve 110 is heated, it is possible to suppress thermal uniformity from deteriorating or an output of the heater 115 from increasing due to heat radiation from the heat sink 210. The housing 230 is formed with an opening 231 at a position corresponding to each of the plurality of insertion through-holes 211 formed in the heat sink 210. The screw 240 is inserted through each opening 231. The housing 230 includes an introduction port 232 and an exhaust port 233.

The introduction port 232 is provided to introduce a refrigerant into the housing 230, and the refrigerant is introduced into the housing 230 via the introduction port 232. The introduction port 232 is provided on one side surface of the housing 230 in the lateral direction. However, the introduction port 232 may be provided on the other side surface of the housing 230. When the gas valve 110 is cooled, the refrigerant is introduced from the introduction port 232, whereby the heat dissipation of the heat sink 210 is promoted. On the other hand, when the gas valve 110 is heated, the introduction of the refrigerant from the introduction port 232 is stopped. By using the refrigerant in this way, unlike a case of using a cooling fan which may be an ignition source, it can be used even in an atmosphere in which a flammable gas is present. The type of the refrigerant is not particularly limited, but the refrigerant is preferably compressed air. By selecting the compressed air as the refrigerant, the compressed air remaining in the housing 230 when the gas valve 110 is heated forms an air heat insulating layer which suppresses the heat dissipation of the heat sink 210. However, the refrigerant may be cold air generated from compressed air by a jet cooler (hereinafter, also simply referred to as “cold air”). By selecting the cold air as the refrigerant, the heat dissipation of the heat sink 210 is further promoted. The reason why the compressed air or the cold air is selected as the refrigerant is that there is no danger of leakage, unlike liquids, flammable gases, and toxic gases. For example, when the compressed air or the cold air is selected as the refrigerant, since there is no danger of leakage, inexpensive components such as one-touch joints may be used for the introduction port 232. This allows an air tube configured to introduce the compressed air or the cold air to be easily attached/detached. The supply and stop of the compressed air or the cold air may be controlled by, for example, an electromagnetic valve. Further, a flow rate of the compressed air or the cold air may be controlled by, for example, an orifice and a regulator.

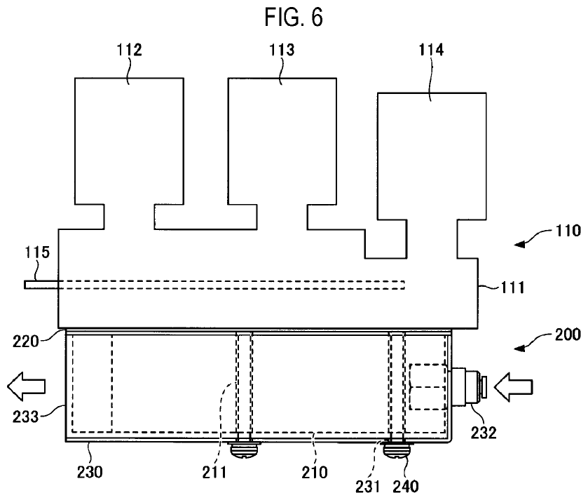

The exhaust port 233 is provided to exhaust the refrigerant from the inside of the housing 230, and the refrigerant in the housing 230 is exhausted through the exhaust port 233. It is preferable that the exhaust port 233 is provided on the side surface of the housing 230 facing the one side surface on which the introduction port 232 is provided. As a result, the refrigerant flows from one end to the other end of the heat sink 210, such that the heat dissipation of the heat sink 210 is further promoted. When the gas valve 110 is cooled, the refrigerant in the housing 230 is exhausted from the exhaust port 233, whereby a new refrigerant is continuously introduced into the housing 230 from the introduction port 232, such that the heat dissipation of the heat sink 210 is promoted. On the other hand, when the gas valve 110 is heated, the exhaust of the refrigerant from the exhaust port 233 is stopped. For example, when the compressed air or the cold air is selected as the refrigerant, inexpensive components such as one-touch joints may be used for the exhaust port 233. This allows an air tube configured to exhaust the compressed air or the cold air to be easily attached/detached. Further, when the compressed air or the cold air is selected as the refrigerant, as shown in FIG. 6, the exhaust port 233 may be an opening having one of the side surfaces of the housing 230 opened. FIG. 6 is a side view showing another example of the cooling unit attached to the gas valve.

The screw 240 is inserted through the opening 231 and the insertion through-hole 211 to fix the housing 230 to the lower surface of the flow path block 111. However, the housing 230 may be fixed to the flow path block 111 by a method other than the screw 240, for example, an adhesive member such as an adhesive tape.

### [Evaluation Results]

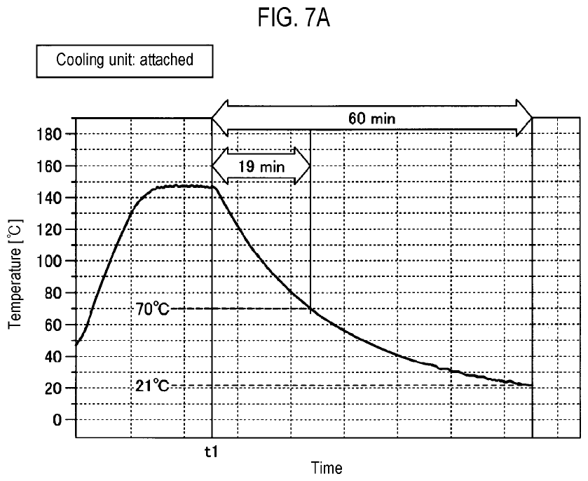

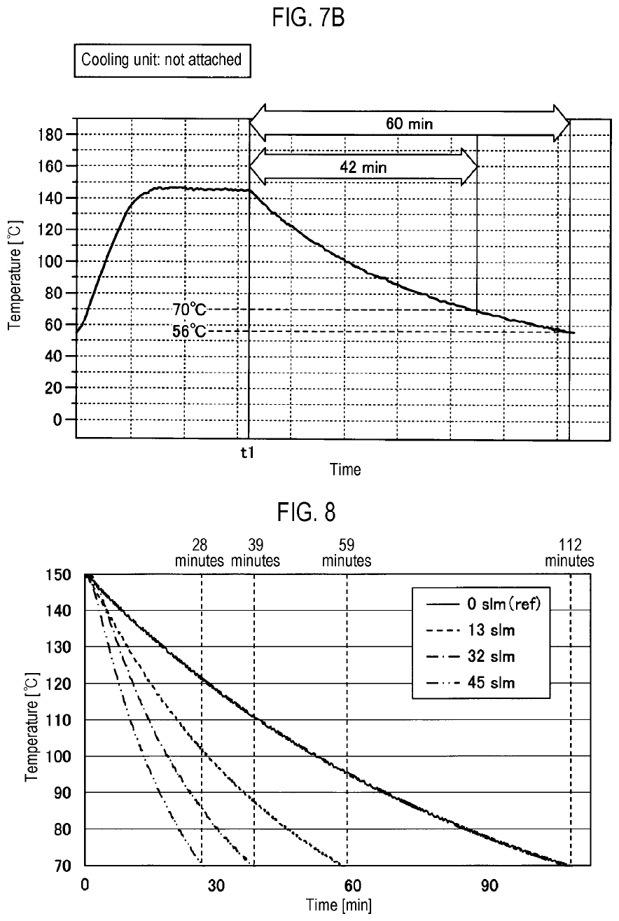

The result of evaluating the cooling performance when the heated gas valve 110 is cooled by the cooling unit 200 of the embodiment of the present disclosure will be described with reference to FIGS. 7A, 7B, and 8.

First, after the gas valve 110 to which the cooling unit 200 of the embodiment was attached was heated by the heater 115 and stabilized at 150 degrees C., a temperature change of the gas valve 110 when the heater 115 was turned off and cold air was introduced into the housing 230 from the introduction port 232 was measured.

Further, for comparison, after the gas valve 110 to which the cooling unit 200 was not attached was heated by the heater 115 and stabilized at 150 degrees C., a temperature change of the gas valve 110 when the heater 115 was turned off was measured.

FIGS. 7A and 7B are diagrams showing the evaluation result of the cooling time of the gas valve 110. FIG. 7A shows the measurement result of the temperature change of the gas valve 110 to which the cooling unit 200 of the embodiment is attached, and FIG. 7B shows the measurement result of the temperature change of the gas valve 110 to which the cooling unit 200 is not attached. In FIGS. 7A and 7B, the horizontal axis represents time and the vertical axis represents the temperature [degrees C.] of the gas valve 110. Further, in FIGS. 7A and 7B, the time when the heater 115 is turned off is indicated by t1.

As shown in FIG. 7A, in the gas valve 110 to which the cooling unit 200 was attached, the time from turning-off of the heater 115 until the temperature of the gas valve 110 dropped to 70 degrees C. was 19 minutes. Further, in the gas valve 110 to which the cooling unit 200 was attached, the temperature of the gas valve 110 at the point of time when 60 minutes had passed after the heater 115 was turned off was 21 degrees C.

On the other hand, as shown in FIG. 7B, in the gas valve 110 to which the cooling unit 200 was not attached, the time from turning-off of the heater 115 until the temperature of the gas valve 110 dropped to 70 degrees C. was 42 minutes. Further, in the gas valve 110 to which the cooling unit 200 was not attached, the temperature of the gas valve 110 at the point of time when 60 minutes had passed after the heater 115 was turned off was 56 degrees C.

From the above results, it was revealed that the time required to cool the gas valve 110 could be shortened by attaching the cooling unit 200 to the gas valve 110 and introducing the cold air into the housing 230 from the introduction port 232.

Next, when the temperature of the gas valve 110 to which the cooling unit 200 of the embodiment was attached dropped from 150 degrees C., the flow rate of the cold air introduced into the housing 230 from the introduction port 232 was changed, and the effect of the flow rate of the cold air on the cooling time of the gas valve 110 was evaluated.

FIG. 8 is a diagram showing the evaluation result of the cooling time of the gas valve 110. In FIG. 8, the horizontal axis represents time [minutes], and the vertical axis represents the temperature [degrees C.] of the gas valve 110. In FIG. 8, a solid line, a broken line, a one-dot chain line, and a two-dot chain line indicate the results when the flow rates of the cold air are 0 slm, 13 slm, 32 slm, and 45 slm, respectively.

As shown in FIG. 8, it can be seen that the temperature drop rate of the gas valve 110 increases by increasing the flow rate of the cold air. Specifically, when the flow rates of the cold air were 0 slm, 13 slm, 32 slm, and 45 slm, the time for the temperature of the gas valve 110 to drop from 150 degrees C. to 70 degrees C. was 112 minutes, 59 minutes, 39 minutes, and 28 minutes, respectively.

From the above-described results, it was revealed that the time required to cool the gas valve 110 could be shortened by increasing the flow rate of the cold air introduced into the housing 230 from the introduction port 232.

In the above-described embodiment, the cooling unit 200 is an example of a temperature control unit, and the refrigerant is an example of a temperature control fluid.

The embodiment disclosed this time should be considered to be exemplary and not restrictive in all respects. The above-described embodiment may be omitted, replaced, or changed in various forms without departing from the appended claims and the gist thereof.

In the above-described embodiment, as an example of the temperature control unit configured to control the temperature of the gas valve 110, the cooling unit 200 that cools the gas valve 110 with the refrigerant has been described, but the present disclosure is not limited thereto. For example, the temperature control unit may be a heating unit that heats the gas valve 110 with a heat medium.

According to the present disclosure in some embodiments, it is possible to control a temperature of a gas valve in a short time.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A temperature control unit that controls a temperature of a gas valve, comprising:
a heat sink attached to the gas valve; and
a housing that covers the heat sink and includes an introduction port through which a temperature control fluid is introduced.

2. The temperature control unit of claim 1, wherein the housing includes an exhaust port through which the temperature control fluid introduced from the introduction port is exhausted.

3. The temperature control unit of claim 2, wherein the housing is attached to the gas valve.

4. The temperature control unit of claim 3, further comprising: a heat conductive member provided between the gas valve and the heat sink.

5. The temperature control unit of claim 4, wherein the temperature control fluid is compressed air.

6. The temperature control unit of claim 5, wherein the temperature control fluid is cold air generated from compressed air by a jet cooler.

7. The temperature control unit of claim 6, wherein the gas valve is heated by a heater.

8. The temperature control unit of claim 7, wherein the gas valve includes a flow path block in which a gas flow path is formed.

9. The temperature control unit of claim 1, wherein the housing is attached to the gas valve.

10. The temperature control unit of claim 1, further comprising: a heat conductive member provided between the gas valve and the heat sink.

11. The temperature control unit of claim 1, wherein the temperature control fluid is compressed air.

12. The temperature control unit of claim 1, wherein the temperature control fluid is cold air generated from compressed air by a jet cooler.

13. The temperature control unit of claim 1, wherein the gas valve is heated by a heater.

14. The temperature control unit of claim 1, wherein the gas valve includes a flow path block in which a gas flow path is formed.

15. A processing apparatus comprising:
a process container;
a gas supply pipe configured to supply a gas into the process container;
a gas valve interposed in the gas supply pipe; and
a temperature control unit configured to control a temperature of the gas valve,
wherein the temperature control unit includes:
a heat sink attached to the gas valve; and
a housing that covers the heat sink and includes an introduction port through which a temperature control fluid is introduced.
